(19) United States
(12) Patent Application Publication
(10) Pub. No.: US 2014/0197374 A1
(43) Pub. Date: Jul. 17, 2014

(54) METHOD FOR MANUFACTURING A NITRIDE SEMICONDUCTOR LIGHT EMITTING DEVICE AND NITRIDE SEMICONDUCTOR LIGHT EMITTING DEVICE MANUFACTURED THEREBY

(71) Applicants: Seok Min Hwang, Pusan (KR); Jin Bock Lee, Osan-si (KR); Tae Sung Jang, Hwaseong-si (KR); Jong Gun Woo, Suwon-si (KR)

(72) Inventors: Seok Min Hwang, Pusan (KR); Jin Bock Lee, Osan-si (KR); Tae Sung Jang, Hwaseong-si (KR); Jong Gun Woo, Suwon-si (KR)

(73) Assignee: SAMSUNG ELECTRONICS CO., LTD., Suwon-si, Gyeonggi-do (KR)

(21) Appl. No.: 14/239,231

(22) PCT Filed: Aug. 17, 2011
(86) PCT No.: PCT/KR2011/006013

§ 371 Date: Feb. 17, 2014

(51) Int. Cl. H01L 33/40

(52) U.S. Cl. CPC H01L 33/405
USPC 257/13; 438/29

(57) ABSTRACT

There is provided a method of manufacturing a nitride semiconductor light emitting device, the method including: forming a light emitting structure on a substrate, the light emitting structure including first and second conductivity-type nitride semiconductor layers with an active layer interposed therebetween; forming a first conductivity-type nitride semiconductor layer, an active layer and a second conductivity-type nitride semiconductor layer sequentially stacked on a substrate; forming a first electrode to be connected to the first conductivity-type nitride semiconductor layer; forming a photoresist film on the second conductivity-type nitride semiconductor layer to expose a portion of the second conductivity-type nitride semiconductor layer; and forming a reflective metal layer and a barrier metal layer as a second electrode consecutively on the portion of the second conductivity-type nitride semiconductor layer exposed by the photoresist film and removing the photoresist film.

### TECHNICAL FIELD

The present disclosure relates to a method of manufacturing a nitride semiconductor light emitting device and a nitride semiconductor light emitting device manufactured using the same, and more particularly, to a method of manufacturing a nitride semiconductor light emitting device capable of enlarging a light emitting region of an active layer while reducing the number of photoresist and lithography processes by simplifying processes for forming electrodes.

### BACKGROUND ART

In recent years, displaying a full range of color has been made in accordance with development of light emitting devices capable of emitting blue, green, and ultraviolet rays using gallium nitride (GaN)-based compound semiconductors. GaN-based compound semiconductor crystals may be grown on an insulating substrate such as a sapphire substrate, but for this reason, no electrode may be formed on a rear surface of the substrate. Therefore, both electrodes should be formed at the side of semiconductor layers grown on the substrate. To this end, it is necessary to use a process for forming a mesa structure in which an upper semiconductor layer and an active layer are partially removed to expose a portion of a top surface of a lower semiconductor layer.

In addition, in a case in which a semiconductor light emitting device is flip-chip bonded to a substrate, light generated in an active layer is emitted externally after passing through an n-type semiconductor layer and the substrate. Light, among the light generated in the active layer, emitted at an angle greater than a critical angle calculated based on refractive index of the n-type semiconductor layer and the substrate may be reflected at a boundary surface between the n-type semiconductor layer and the substrate and may be emitted through side surfaces of the device while being repeatedly reflected between p-type and n-type electrodes and the substrate. As the reflection is repeated, energy of light may be absorbed by the p-type and n-type electrodes, whereby intensity of light may be significantly decreased.

In order to improve light extraction efficiency of the semiconductor light emitting device, the electrodes need to be formed of a material having high light reflectivity, such as Ag, Au, Pt or the like used in the form of an alloy. However, in the case in which such a metal, especially Ag, is used in a reflective electrode, when it is treated at high temperatures, agglomeration and voids at an interface may be generated due to low thermal stability. In order to avoid this, a barrier metal layer may be formed on a reflective metal layer. Then, a bonding electrode may be formed on the barrier metal layer. To this end, the number of photoresist formation, photoresist removal, and deposition processes may increase.

Furthermore, when the barrier metal layer is formed on the reflective metal layer, openings in a mask layer may be used to implement selective deposition. The openings in the mask layer may be determined taking into account manufacturing error in the electrode forming process, and in particular, it is necessary to sufficiently consider a distance between the barrier metal layer and the electrode in order to allow the entirety of the electrode to be formed on the barrier metal layer. Here, in a case in which the distance between the barrier metal layer and the electrode is increased, an area of the barrier metal layer may be enlarged, resulting in a reduction in a light emitting area.

### DISCLOSURE

### Technical Problem

An aspect of the present disclosure provides a method of manufacturing a nitride semiconductor light emitting device including forming a p-type electrode by simultaneously depositing a reflective metal layer and a barrier metal layer on a p-type semiconductor layer through a single photoresist process, and a nitride semiconductor light emitting device manufactured using the same.

### Technical Solution

According to an aspect of the present disclosure, there is provided a method of manufacturing a nitride semiconductor light emitting device, the method including: forming a light emitting structure on a substrate, the light emitting structure including first and second conductivity-type nitride semiconductor layers with an active layer interposed therebetween; forming a first conductivity-type nitride semiconductor layer, an active layer and a second conductivity-type nitride semiconductor layer sequentially stacked on a substrate; forming a first electrode to be connected to the first conductivity-type nitride semiconductor layer; forming a photoresist film on the second conductivity-type nitride semiconductor layer to expose a portion of the second conductivity-type nitride semiconductor layer; and forming a reflective metal layer and a barrier metal layer as a second electrode consecutively on the portion of the second conductivity-type nitride semiconductor layer exposed by the photoresist film and removing the photoresist film.

The forming of the reflective metal layer and the barrier metal layer may include forming the reflective metal layer; and consecutively forming the barrier metal layer to cover top and side surfaces of the reflective metal layer in a state of maintaining the photoresist film.

The forming of the reflective metal layer and the barrier metal layer may include forming the reflective metal layer through e-beam evaporation; and forming the barrier metal layer through sputter deposition.

The forming of the reflective metal layer and the barrier metal layer may include depositing the reflective metal layer using an e-beam evaporator having a first stack coverage; and depositing the barrier metal layer using a sputter having a second stack coverage higher than the first stack coverage.

The forming of the reflective metal layer and the barrier metal layer may include depositing the reflective metal layer using an e-beam evaporator having a first stack coverage; and depositing the barrier metal layer using an e-beam evaporator having a second stack coverage higher than the first stack coverage.

The barrier metal layer may be formed to cover top and side surfaces of the reflective metal layer such that a portion thereof covering the top surface is thicker than a portion thereof covering the side surfaces.

The method may further include forming a passivation layer on an entirety of a top surface of the light emitting structure.

The photoresist film may be formed of a negative photoresist.

The method may further include forming a bonding metal layer on the barrier metal layer.

According to another aspect of the present disclosure, there is provided a nitride semiconductor light emitting device, including: first and second conductivity-type nitride semiconductor layers; an active layer interposed between the first and second conductivity-type nitride semiconductor layers; a first electrode electrically connected to the first conductivity-type nitride semiconductor layer; and a second electrode including a reflective metal layer formed on the second conductivity-type nitride semiconductor layer, and a barrier metal layer formed to cover top and side surfaces of the reflective metal layer while a portion thereof covering the top surface is thicker than a portion thereof covering the side surfaces.

The first and second conductivity-type nitride semiconductor layers and the active layer may be formed on a substrate having light transmissive and electrical insulating properties.

The nitride semiconductor light emitting device may further include a conductive support substrate formed on the second electrode, and the first electrode may be formed on a surface of the first conductivity-type nitride semiconductor layer in a direction opposite to the second conductivity-type nitride semiconductor layer.

The nitride semiconductor light emitting device may further include at least one conductive via penetrating through the active layer and the second conductivity-type nitride semiconductor layer to be connected to the first conductivity-type nitride semiconductor layer, and the first electrode may be connected to the conductive via and is externally exposed.

The nitride semiconductor light emitting device may further include a bonding metal layer formed on the barrier metal layer.

### Advantageous Effects

As set forth above, according to an exemplary embodiment of the present disclosure, a manufacturing process may be simplified by reducing the number of photoresist formation and removal processes, and an area of a barrier metal layer may be reduced to decrease an amount of light absorbed by the barrier metal layer. In addition, the barrier metal layer may be attached to a reflective metal layer through capping to thereby prevent agglomeration and voids at an interface therebetween generated at the time of heat-treating the reflective metal layer, whereby reliability of a light emitting device may be secured. Furthermore, according to another exemplary embodiment of the present disclosure, a light emitting area may be enlarged to improve luminous intensity.

### DESCRIPTION OF DRAWINGS

FIG. 1 is a side cross-sectional view schematically illustrating a nitride semiconductor light emitting device according to an exemplary embodiment of the present disclosure;

FIGS. 2 through 9 are side cross-sectional views illustrating a method of manufacturing the nitride semiconductor light emitting device of FIG. 1;

FIG. 10 is cross-sectional views illustrating a comparison of electrode structures of a nitride semiconductor light emitting device according to an exemplary embodiment of the present disclosure and a nitride semiconductor light emitting device according to the related art;

FIGS. 11A and 11B are views illustrating a process of depositing a reflective metal layer and a barrier metal layer by comparing a case of using a negative photoresist illustrated in FIG. 11A with a case of using a positive photoresist illustrated in FIG. 11B; and

FIGS. 12 and 13 are cross-sectional views schematically illustrating a nitride semiconductor light emitting device according to another exemplary embodiment of the present disclosure.

### BEST MODE

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

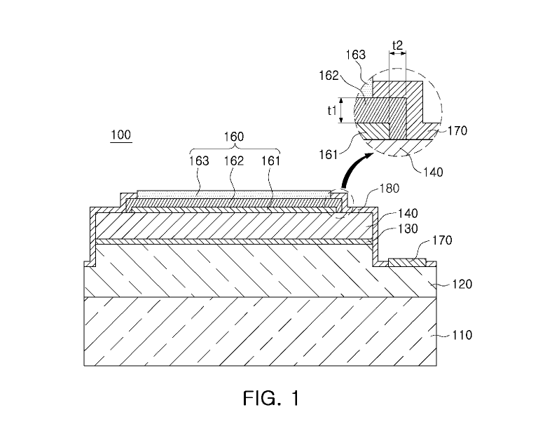

FIG. 1 is a side cross-sectional view schematically illustrating a nitride semiconductor light emitting device according to an exemplary embodiment of the present disclosure.

With reference to FIG. 1, a nitride semiconductor light emitting device 100 according to an exemplary embodiment of the present disclosure may include a first conductivity-type nitride semiconductor layer 120, an active layer 130 and a second conductivity-type nitride semiconductor layer 140 sequentially stacked on a top surface of a substrate 110. In addition, a first electrode 170 may be formed on a portion of the first conductivity-type nitride semiconductor layer 120 exposed by mesa-etching, and a second electrode 160 may be formed on the second conductivity-type nitride semiconductor layer 140. A passivation layer 180 may be formed on surfaces (side and top surfaces) of the semiconductor layers 120, 130 and 140 while allowing regions in which the first and second electrodes 170 and 160 are formed to be open. The passivation layer 180 may protect a light emitting structure and form electrical insulation between the individual layers and the electrodes.

The substrate 110 may be used for growing nitride semiconductor layers. The substrate 110 may be a high resistance substrate, and a sapphire substrate is mainly used therefor. Sapphire is a crystal having Hexa-Rhombo R3C symmetry and has a lattice constant of 13.00 Å along a C-axis and a lattice constant of 4.758 Å along an A-axis. Orientation planes of sapphire include a C (0001) plane, an A (1120) plane, an R (1102) plane, and the like. The C plane is mainly used as a substrate for nitride semiconductor growth because it facilitates growth of a nitride film and is stable at high temperatures. However, the substrate 110 according to the present embodiment is not limited to the sapphire substrate, and a substrate formed of SiC, Si, GaN, AlN or the like, besides the sapphire substrate, may also be used.

The first conductivity-type nitride semiconductor layer 120 and the second conductivity-type nitride semiconductor layer 140 may be formed of a material having a composition expressed by AlₓIn_{y}Ga_{(1-x-y)}N, where 0≦x≦1, 0≦y≦1, and 0≦x+y≦1, and may be doped with n-type and p-type impurities, respectively. The first and second conductivity-type nitride semiconductor layers 120 and 140 may be grown by a known method related to growth of nitride semiconductor layers, for example, metal organic chemical vapor deposition (MOCVD), molecular beam epitaxy (MBE), hydride vapor phase epitaxy (HVPE), or the like.

Although not illustrated, a buffer layer (not shown) may be formed on the substrate 110 in order to alleviate a lattice mismatch between the substrate 110 and the first conductivity-type nitride semiconductor layer 120. The buffer layer may be an n-type material layer or an undoped material layer formed of group III-V nitride compound semiconductors. The buffer layer may be an AlN nucleation layer or an n-GaN nucleation layer grown at low temperatures.

The active layer 130 may be a material layer emitting light through electron-hole carrier recombination and may be formed of a GaN-based semiconductor layer made of group III-V nitride compound semiconductors having a multi-quantum well (MQW) structure in which quantum well layers and quantum barrier layers are alternately stacked. Here, the quantum barrier layers may have a composition expressed by AlₓIn_{y}Ga_{(1-x-y)}N, where 0≦x≦1, 0<y≦1, and 0<x+y≦1, and the quantum well layers may have a composition expressed by In_{z}Ga_{(1-z)}N, where 0≦z≦1. Here, the quantum barrier layers may have a superlattice structure having a thickness enabling tunneling of holes injected from the second conductivity-type nitride semiconductor layer 140.

Although not illustrated, a transparent conductive oxide (TCO) film may further be formed between the first conductivity-type nitride semiconductor layer 140 and the second electrode 160. In addition, in a case in which the TCO film or a metal layer made of nickel (Ni), titanium (Ti), chrome (Cr), aluminum (Al) or the like is formed between the first conductivity-type nitride semiconductor layer 140 and the second electrode 160, bonding strength between a pad electrode and a light transmissive electrode may be increased. In particular, in the case of using nickel (Ni), the bonding strength may be further increased.

In the present embodiment, the second electrode 160 may include a reflective metal layer 161 and a barrier metal layer 162 sequentially stacked therein, and if necessary, a bonding metal layer 163 may be further formed thereon. The reflective metal layer 161 may be formed of a material having high reflectivity and forming an ohmic-contact with the second conductivity-type nitride semiconductor layer 140, and for example, any one metal selected from the group consisting of Ag, Al, Au and alloys thereof, may be used therefor. In addition, the barrier metal layer 162 may be formed to cover top and side surfaces of the reflective metal layer 161 and may be made of TiW or the like. The barrier metal layer 162 may prevent the reflective metal layer 161 from being fused at interfaces with a material of the bonding metal layer 163 and a material of the reflective metal layer 161, so as to avoid deterioration of the properties (especially, reflectivity and contact resistance) of the reflective metal layer 161. In the present embodiment, the barrier metal layer 162, as illustrated in FIG. 1, may be formed to cover the top and side surfaces of the reflective metal layer 161, and a thickness t1 of a portion of the barrier metal layer 162 covering the top surface of the reflective metal layer 161 may be greater than a thickness t2 of a portion of the barrier metal layer 162 covering the side surfaces of the reflective metal layer 161. As described hereinafter, such a structure may be obtained when a deposition process proposed in the present inventive concept is implemented. The bonding metal layer 163 may be, for example, made of Cr/Au. Meanwhile, the first electrode 170 may be formed of a bonding metal layer and form an ohmic-contact with the first conductivity-type nitride semiconductor layer 120.

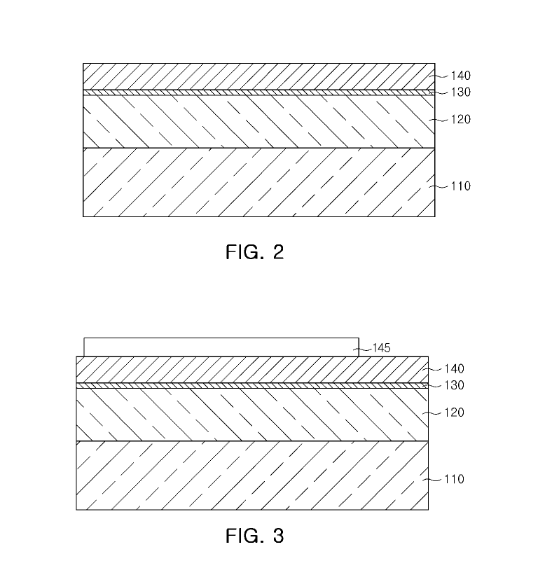

Hereinafter, a method of manufacturing the nitride semiconductor light emitting device 100 of FIG. 1 will be described. FIGS. 2 through 7 are side cross-sectional views illustrating each process in the method of manufacturing the nitride semiconductor light emitting device of FIG. 1.

First, with reference to FIG. 2, the first conductivity-type nitride semiconductor layer 120, the active layer 130 and the second conductivity-type nitride semiconductor layer 140 may sequentially be epitaxially grown on the substrate 110 to form a light emitting structure. These nitride semiconductor layers 120, 130 and 140 may be grown by MOCVD, or the like.

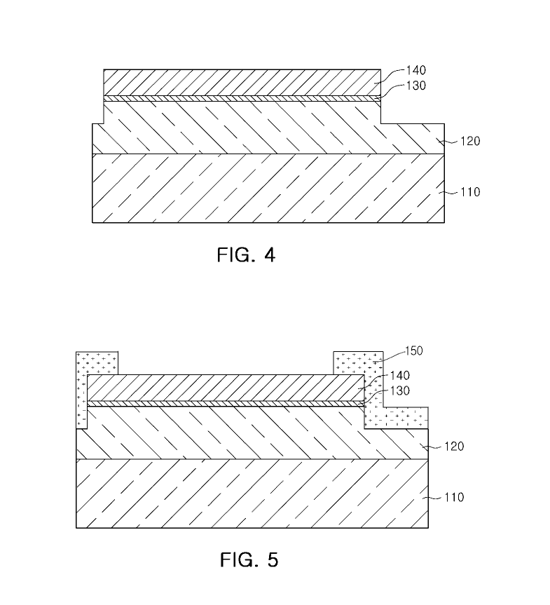

Next, with reference to FIGS. 3 and 4, a mesa structure may be formed in order to form respective electrodes on the nitride semiconductor layers 120 and 140. As illustrated in FIG. 3, the mesa structure may be obtained by forming a photoresist film 145 on a top surface of the second conductivity-type nitride semiconductor layer 140 excluding a portion thereof to be etched. Thereafter, as illustrated in FIG. 4, the second conductivity-type nitride semiconductor layer 140 and the active layer 130 may be partially etched and removed to expose the first conductivity-type nitride semiconductor layer 120, whereby the mesa structure may be formed. Then, the photoresist film 145 used to form the mesa structure may be removed therefrom.

Next, with reference to FIG. 5, a photoresist film 150 having an opening in a region for forming the second electrode may be formed. Here, the second electrode may have a multilayer structure formed of the reflective metal layer and the barrier metal layer as described above. A portion of the top surface of the second conductivity-type nitride semiconductor layer 140 exposed by the photoresist film 150 may be smaller than the entire top surface thereof, which is intended to prepare a margin in a metal deposition process.

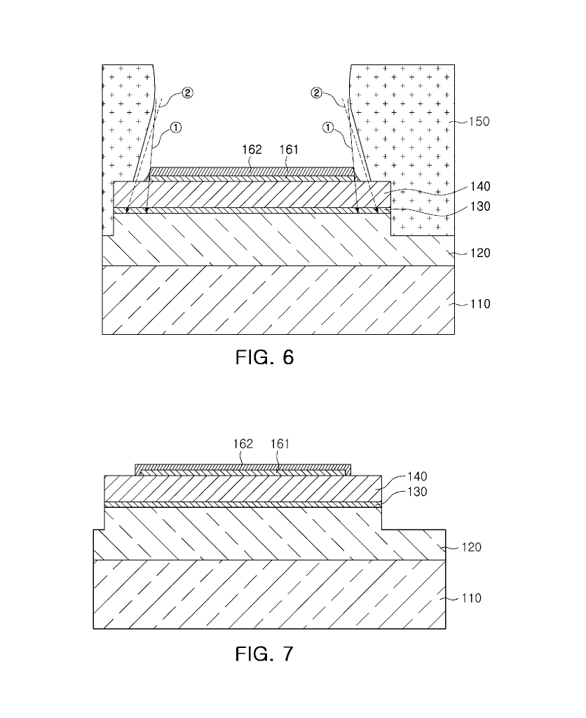

Then, with reference to FIG. 6, the photoresist film 150 having the opening in the region for forming the second electrode 160 may be formed on the top surface of the second conductivity-type nitride semiconductor layer 140, and the multilayer structure formed of the reflective metal layer 161 and the barrier metal layer 162 may be formed through e-beam evaporation or sputter deposition. Here, the photoresist film 150 of FIG. 5 is illustrated as an enlarged view of the photoresist film 150 of FIG. 4.

Here, the reflective metal layer 161 and the barrier metal layer 162 may be individually deposited using devices having different ranges of stack coverage. For example, after the reflective metal layer 161 is formed using an e-beam evaporator \hat{1} having low stack coverage, the barrier metal layer 162 is deposited to cover the top and side surfaces of the reflective metal layer 161 using an e-beam evaporator \hat{2} having high stack coverage in a state in which the photoresist film 150 is maintained. Alternatively, the reflective metal layer 161 may be formed through the e-beam evaporation, and the barrier metal layer 162 may be formed through sputter deposition. This is because a sputter has higher stack coverage than an e-beam evaporator. That is, the reflective metal layer 161 may be formed using the e-beam evaporator, and the barrier metal layer 162 may be formed using the sputter having higher stack coverage than the e-beam evaporator. In this case, since the barrier metal layer 162 may be formed after the reflective metal layer 161 is formed using the single photoresist film 150, the barrier metal layer 162 may be formed as illustrated in FIG. 6 such that a portion thereof covering the top surface of the reflective metal layer is thicker than a portion thereof covering the side surfaces of the reflective metal layer. Subsequently, heat treatment may be performed, and the photoresist film 150 used to form the reflective metal layer 161 and the barrier metal layer 162 may be removed to thereby obtain a structure illustrated in FIG. 7.

As described above, a general method of manufacturing a nitride semiconductor light emitting device may be improved to implement the process of forming the reflective metal layer 161 and the barrier metal layer 162 using a single photoresist film according to the present inventive concept. Since only a single photoresist film is formed, the number at which photoresist film removal and washing processes are performed following the formation of the photoresist film may be reduced, whereby the manufacturing process may be simplified. In addition, the barrier metal layer 162 may be attached to the reflective metal layer 161 through capping, and in particular, in a case in which the reflective metal layer 161 is formed of silver (Ag), loss of silver (Ag) caused by the removal of the photoresist film and the formation of voids at an interface may be prevented, whereby reliability of the light emitting device may be stably secured. Furthermore, since a single photoresist process is needed, a margin for electrodeposition may be minimized. Thus, an area of the second electrode, that is, an effective area of current injection, may be increased, resulting in improvement of light emitting efficiency.

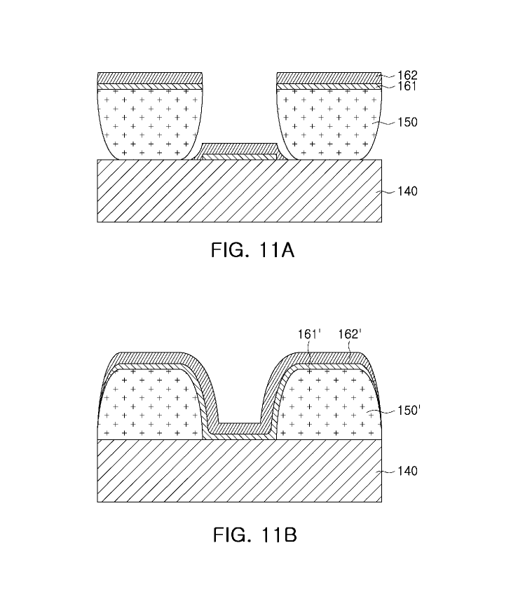

Meanwhile, the photoresist film 150 used in the present embodiment may be a negative photoresist. With reference to FIG. 11, the process of depositing the reflective metal layer and the barrier metal layer will be explained by comparing a case of using a negative photoresist illustrated in FIG. 11A with a case of using a positive photoresist illustrated in FIG. 11B. In the case of using a negative photoresist (allowing a portion irradiated with light to remain) as illustrated in FIG. 11A, the reflective metal layer 161 and the barrier metal layer 162 are separated into portions formed on the second conductivity-type nitride semiconductor layer 140 and portions formed on the photoresist film 150, and thus, the photoresist film 150 may be easily removed through a subsequent lift-off process. On the other hand, in the case of using a positive photoresist (allowing a portion non-irradiated with light to remain) as illustrated in FIG. 11B, a reflective metal layer 161′ and a barrier metal layer 162′ are continuously formed, rendering the removal of a photoresist film 150′ to be difficult.

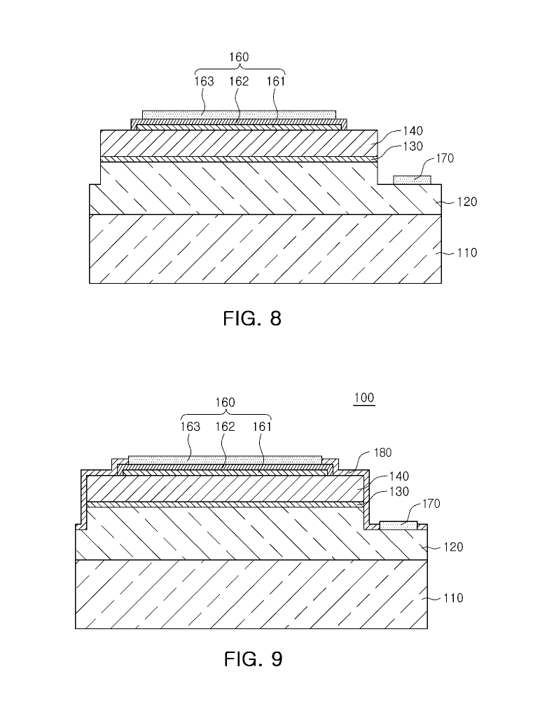

Next, with reference to FIG. 8, the bonding metal layer and the first electrode may be formed on the barrier metal layer 162 and the exposed portion of the first conductivity-type nitride semiconductor layer 120, respectively. The formation of the bonding metal layer may be implemented by forming a photoresist film (not shown) having an opening in a region for forming the first electrode in order to expose a portion of the first conductivity-type nitride semiconductor layer 120, forming the first electrode 170 on the exposed portion of the first conductivity-type nitride semiconductor layer 120, and removing the photoresist film. Thereafter, a photoresist film (not shown) having an opening in a region for forming the bonding metal layer 163 may be formed to expose a portion of the barrier metal layer 162. After the bonding metal layer 163 is formed, the photoresist film is removed. As a result, a structure illustrated in FIG. 8 may be obtained.

Then, with reference to FIG. 9, the passivation layer 180 may be formed on the structure of FIG. 8. Specifically, the formation of the passivation layer 180 may be implemented by forming an insulating layer on the entirety of a top surface of the structure of FIG. 8, that is, on the exposed portions of the first conductivity-type nitride semiconductor layer 120 and the second conductivity-type nitride semiconductor layer 140. The insulating layer may be formed of SiO₂ or SiN. After a photoresist film (not shown) with an opening exposing the first electrode 170 and the bonding metal layer 163 of the second electrode 160 is formed on the insulating layer, the insulating layer may be selectively removed by etching, thereby forming the passivation layer 180. As a result, a final nitride semiconductor light emitting device 100 may be manufactured as illustrated in FIG. 9.

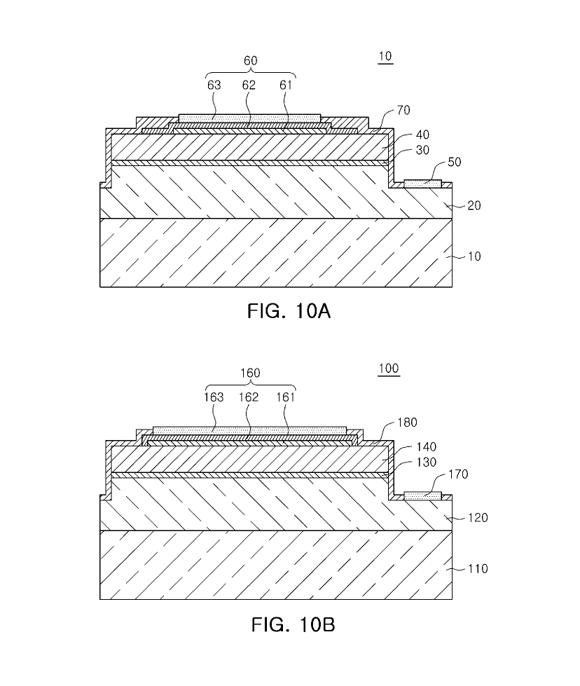

FIG. 10 is cross-sectional views illustrating comparison of electrode structures of a nitride semiconductor light emitting device according to an exemplary embodiment of the present disclosure and a nitride semiconductor light emitting device according to the related art. Here, FIG. 10A is a side cross-sectional view of a general nitride semiconductor light emitting device 10 manufactured by forming a reflective metal layer and a barrier metal layer by performing photoresist formation and removal processes twice, and FIG. 10B is a side cross-sectional view of the nitride semiconductor light emitting device 100 according to the exemplary embodiment of the present disclosure manufactured by forming the reflective metal layer and the barrier metal layer through a single photoresist process.

With reference to FIGS. 10A and 10B, since a reflective metal layer 61 and a barrier metal layer 62 of the related art nitride semiconductor light emitting device 10 are formed through two photoresist processes, it is necessary to sufficiently consider the size of openings after taking into account errors in margins at the time of forming the openings in individual mask layers. Thus, the region for forming the barrier metal layer 62 is larger than the region for forming the barrier metal layer 162 of the nitride semiconductor light emitting device 100 according to the exemplary embodiment of the present disclosure. Therefore, the nitride semiconductor light emitting device 100 according to the embodiment of the present disclosure may address a problem in which a light emitting area is decreased by the barrier metal layer 62 of the related art nitride semiconductor light emitting device 10. That is, the nitride semiconductor light emitting device 100 according to the embodiment of the present disclosure may decrease an area of the barrier metal layer 162 and increase an area of the reflective metal layer 161, whereby a light emitting area may be increased.

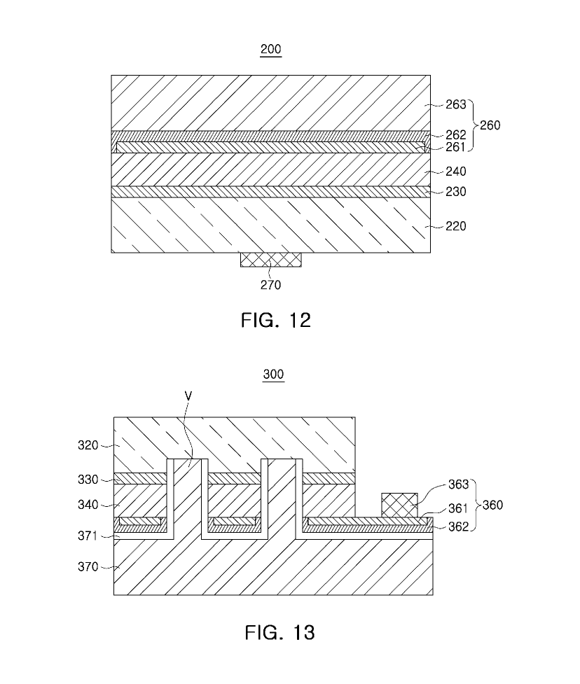

FIGS. 12 and 13 are cross-sectional views schematically illustrating a nitride semiconductor light emitting device according to another exemplary embodiment of the present disclosure. In the aforementioned embodiment, the pair of electrodes connected to the device are disposed toward the top of the device, and the semiconductor growth substrate 110 is included in the final device. In the embodiment of FIG. 12, a nitride semiconductor light emitting device 200 may include a first conductivity-type semiconductor layer 220, an active layer 230 and a second conductivity-type semiconductor layer 240, and a second electrode 260 including a reflective metal layer 261, a barrier metal layer 262 and a conductive support substrate 263 may be formed on the second conductivity-type semiconductor layer 240. In addition, a first electrode 270 may be formed on a surface of the first conductivity-type semiconductor layer 220 in a direction opposite to the second conductivity-type semiconductor layer 240. In the present embodiment, the performance of the reflective metal layer 261 and the barrier metal layer 262 is highly important in that light emitted from the active layer 230 may be reflected by the reflective metal layer 261 and the reflected light may be led downwards based on FIG. 12. Meanwhile, the conductive support substrate 263 may serve as a support for supporting the light emitting structure in a laser lift-off process or the like for removing the substrate 110 provided for semiconductor growth, and may be formed of a material including at least one of Au, Ni, Al, Cu, W, Si, Se, and GaAs. For example, a SiAl substrate may be used therefor.

A nitride semiconductor light emitting device 300 according to the exemplary embodiment illustrated in FIG. 13 may include a first conductivity-type semiconductor layer 320, an active layer 330 and a second conductivity-type semiconductor layer 340, and a second electrode 360 including a reflective metal layer 361, a barrier metal layer 362 and a bonding metal layer 363 may be formed on the second conductivity-type semiconductor layer 340. In the aforementioned embodiment of FIG. 12, the conductive support substrate 263 is electrically connected to the second conductivity-type semiconductor layer 240; however, in the present embodiment, a support substrate 362 is electrically connected to the first conductivity-type semiconductor layer 320. To this end, a conductive via v electrically connected to the support substrate 362 may penetrate through the active layer 330 and the second conductivity-type semiconductor layer 340 to be connected to the first conductivity-type semiconductor layer 320. In this case, an insulating layer 371 may be interposed to separate the conductive via v from the active layer 330 and the second conductivity-type semiconductor layer 340. A surface of the reflective metal layer 361 interposed between the second conductivity-type semiconductor layer 340 and the support substrate 370 may be partially exposed externally, and the exposed surface thereof may have the bonding metal layer 363 to which external electrical signals are applied formed thereon. In the present embodiment, the barrier metal layer 362 may be formed to cover top and side surfaces of the reflective metal layer 361, such that a portion thereof covering the top surface of the reflective metal layer 361 is thicker than a portion thereof covering the side surfaces of the reflective metal layer 361, which is because a depositing process having different ranges of stack coverage is implemented using a single photoresist film. Here, the top surface of the reflective metal layer 361 may be understood as being a bottom surface thereof in FIG. 13, since it is illustrated in an opposite direction as compared with the aforementioned embodiments.

While exemplary embodiments have been shown and described above, it will be apparent to those skilled in the art that modifications and variations could be made without departing from the spirit and scope of the present disclosure as defined by the appended claims.

1. A method of manufacturing a nitride semiconductor light emitting device, the method comprising:
forming a light emitting structure on a substrate, the light emitting structure including first and second conductivity-type nitride semiconductor layers with an active layer interposed therebetween;
forming a first electrode to be connected to the first conductivity-type nitride semiconductor layer;
forming a photoresist film on the second conductivity-type nitride semiconductor layer to expose a portion of the second conductivity-type nitride semiconductor layer; and
forming a reflective metal layer and a barrier metal layer as a second electrode consecutively on the portion of the second conductivity-type nitride semiconductor layer exposed by the photoresist film and removing the photoresist film.

2. The method of claim 1, wherein the forming of the reflective metal layer and the barrier metal layer includes:
forming the reflective metal layer; and
consecutively forming the barrier metal layer to cover top and side surfaces of the reflective metal layer in a state of maintaining the photoresist film.

3. The method of claim 1, wherein the forming of the reflective metal layer and the barrier metal layer includes:
forming the reflective metal layer through e-beam evaporation; and
forming the barrier metal layer through sputter deposition.

4. The method of claim 1, wherein the forming of the reflective metal layer and the barrier metal layer includes:
depositing the reflective metal layer using an e-beam evaporator having a first stack coverage; and
depositing the barrier metal layer using a sputter having a second stack coverage higher than the first stack coverage.

5. The method of claim 1, wherein the forming of the reflective metal layer and the barrier metal layer includes:
depositing the reflective metal layer using an e-beam evaporator having a first stack coverage; and
depositing the barrier metal layer using an e-beam evaporator having a second stack coverage higher than the first stack coverage.

6. The method of claim 1, wherein the barrier metal layer is formed to cover top and side surfaces of the reflective metal layer such that a portion thereof covering the top surface is thicker than a portion thereof covering the side surfaces.

7. The method of claim 1, further comprising forming a passivation layer on an entirety of a top surface of the light emitting structure.

8. The method of claim 1, wherein the photoresist film is formed of a negative photoresist.

9. The method of claim 1, further comprising forming a bonding metal layer on the barrier metal layer.

10. A nitride semiconductor light emitting device, comprising:
first and second conductivity-type nitride semiconductor layers;
an active layer interposed between the first and second conductivity-type nitride semiconductor layers;
a first electrode electrically connected to the first conductivity-type nitride semiconductor layer; and
a second electrode including a reflective metal layer formed on the second conductivity-type nitride semiconductor layer, and a barrier metal layer formed to cover top and side surfaces of the reflective metal layer while a portion thereof covering the top surface is thicker than a portion thereof covering the side surfaces.

11. The nitride semiconductor light emitting device of claim 10, wherein the first and second conductivity-type nitride semiconductor layers and the active layer are formed on a substrate having light transmissive and electrical insulating properties.

12. The nitride semiconductor light emitting device of claim 10, further comprising a conductive support substrate formed on the second electrode,
wherein the first electrode is formed on a surface of the first conductivity-type nitride semiconductor layer in a direction opposite to the second conductivity-type nitride semiconductor layer.

13. The nitride semiconductor light emitting device of claim 10, further comprising at least one conductive via penetrating through the active layer and the second conductivity-type nitride semiconductor layer to be connected to the first conductivity-type nitride semiconductor layer,
wherein the first electrode is connected to the conductive via and is externally exposed.

14. The nitride semiconductor light emitting device of claim 10, further comprising a bonding metal layer formed on the barrier metal layer.
